(19) United States
(12) Patent Application Publication
(10) Pub. No.: US 2026/0110385 A1
(43) Pub. Date: Apr. 23, 2026

(54) MULTI-LAYER HEAT INSULATED PIPELINE FOR CONVEYING GAS

(71) Applicant: Yu-Tung YIN, New Taipei City (TW)

(72) Inventor: Yu-Tung YIN, New Taipei City (TW)

(21) Appl. No.: 19/365,834

(22) Filed: Oct. 22, 2025

(30) Foreign Application Priority Data
Oct. 22, 2024 (TW) 113140159
Oct. 22, 2024 (TW) 113211446

(51) Int. Cl. F16L 53/30; F16L 11/14; F16L 59/06

(52) U.S. Cl. CPC F16L 53/30; F16L 11/14; F16L 59/06

(57) ABSTRACT

A multi-layer heat insulated pipeline, for conveying a first gas, includes an inner pipeline and an external pipeline. The inner pipeline is disposed within the external pipeline, and has a plurality of orifices. The first gas is conveyed within the inner pipeline along a pumping direction. The external pipeline includes an intake tube. A second gas is firstly heated or cooled and then injected into an interlayer between the external pipeline and the inner pipeline from the intake tube. The second gas is inactive with respect to the first gas. A first pressure of the first gas is less than a second pressure of the second gas.

### CROSS-REFERENCE TO RELATED APPLICATION

This utility application claims priority to Taiwan Application Serial Number 113140159, filed Oct. 22, 2024, and Taiwan Application Serial Number 113211446, filed Oct. 22, 2024, which are incorporated herein by reference.

### BACKGROUND OF THE INVENTION

### 1. Field of the Invention

The invention relates to a multi-layer heat insulated pipeline for conveying a gas, and more particularly, to a multi-layer heat insulated pipeline that reduces energy consumption for temperature control, prevents the formation and deposition of particles and process by-products, and avoids clogging while conveying a gas whose temperature can be controlled or maintained, unaffected by the ambient environment.

### 2. Description of the Prior Art

In the manufacturing processes of semiconductors and optoelectronic components, various thin-film deposition techniques are widely employed. These include Chemical Vapor Deposition (CVD) and Atomic Layer Deposition (ALD), which involve chemical reactions of precursors, as well as Physical Vapor Deposition (PVD), which utilizes plasma sputtering. In these processes, the effective removal of post-reaction precursors and reactive gases in CVD and ALD, and the exhaust of tail gas after PVD, are critical for process yield and productivity. These deposition processes are typically conducted in a vacuum environment within a cleanroom, connected to a facility-side exhaust system for tail gas treatment and discharge. Consequently, the exhaust system must efficiently handle process tail gas, which may include unreacted precursors, reactive gases, process-generated by-products, particles, and corrosive gases.

The aforementioned exhaust systems utilize various pipelines to connect process equipment (e.g., deposition tools) to pumping equipment (e.g., dry pumps) and abatement equipment, for example, the pipelines connecting the process tools to the dry pumps, or the dry pumps to the abatement equipment, etc. Gases transported within these pipelines can lead to particle deposition from the process, accumulation of unreacted precursors and reactive gases, and build-up of process by-products or corrosive gas-induced particles. Such deposition and accumulation cause particle contamination issues that reduce process yield. When the buildup reaches a certain level, it necessitates equipment shutdown for pipeline replacement or cleaning, leading to production delays.

To mitigate particle deposition and by-product accumulation, the pipelines of a prior art are typically wrapped with indirect heating devices. The indirect heating elements employed in the prior art specifically include securing heating wires or resistive heating components onto a woven cloth made of heat-resistant fibers or embedding them within a silicone sheet. An insulating material is then adhered to the outside of the covering surface of the woven cloth or the silicone sheet, resulting in structures such as: insulation material/heating wire/heat-resistant fibers (covering surface) or silicone/heating wire/insulation material. However, because these heating devices of the prior art are adhered to heat-resistant fibers or silicone, they form an indirect heating system, resulting in poor heating efficiency. This indirect heating device design causes the exhaust system to be quite energy-intensive when maintaining a steady temperature. Furthermore, the service life of exhaust lines that are equipped with indirect heating devices in the prior art is limited by the aforementioned deposition or particle buildup, meaning there is significant room for improvement. Additionally, the indirect heating assembly itself-where the other side of the heating device is covered for insulation by heat-resistant fiber filling, silicone, or aerogel-does not offer the best thermal insulation efficiency. Furthermore, there is a risk of fiber breakage, and powdering of the silicone and aerogel, which negatively impacts the cleanliness of the cleanroom.

In addition, the pipelines used in the aforementioned exhaust system are typically rigid piping. However, rigid piping takes longer to configure and install, requires extra fittings for every bend, and also needs corresponding indirect heating devices to wrap around its outer circumference.

### SUMMARY OF THE INVENTION

Accordingly, one scope of the invention is to provide a multi-layer heat insulated pipeline for conveying a gas that prevents particle deposition, accumulation of by-products from unreacted precursors and reactive gases, and clogging, while also reducing the energy consumption required for temperature maintenance.

A multi-layer heat insulated pipeline for conveying a first gas, according to a first preferred embodiment of the invention, includes an inner pipeline and an external pipeline. The first gas is conveyed within the inner pipeline along a pumping direction. The inner pipeline has a plurality of orifices, and is disposed within the external pipeline. The external pipeline includes an intake tube. A second gas, which is non-reactive with respect to the first gas, is selectively injected from the intake tube into a first interlayer between the external pipeline and the inner pipeline. When injected, the second gas is firstly heated or cooled and then injected from the intake tube into the first interlayer between the external pipeline and the inner pipeline. A first pressure of the first gas is less than a second pressure of the second gas.

Further, the multi-layer heat insulated pipeline according to the first preferred embodiment of the invention also includes a thermal insulation layer and a heating device. The inner pipeline and the external pipeline are disposed within the thermal insulation layer. The intake tube extending outside the thermal insulation layer. A second interlayer, between the thermal insulation layer and the external pipeline, is vacuumized. The heating device is attached to an outer periphery of the external pipeline. The heating device is configured to heat the external pipeline.

Further, the multi-layer heat insulated pipeline according to the first preferred embodiment of the invention also includes a plurality of thermal insulation supporting members. These thermal insulation supporting members are intermittently placed on the outer periphery of the external pipeline to space apart an inner periphery of the thermal insulation layer from the heating device.

In one embodiment, an average pore diameter of the plurality of orifices ranges from 1 micrometer to 10 millimeters.

In one embodiment, a distribution density of the plurality of orifices ranges from 0.001 to 1000 orifices per centimeter pipeline length.

A multi-layer heat insulated pipeline for conveying a first gas, according to a second preferred embodiment of the invention, includes a flexible metal hose and an external pipeline. The first gas is conveyed within the flexible metal hose along a pumping direction. The flexible metal hose has a plurality of slits. The flexible metal hose is disposed within the external pipeline. The external pipeline includes an intake tube. The second gas is selectively injected from the intake tube into a first interlayer between the external pipeline and the flexible metal hose. The second gas being non-reactive with respect to the first gas. When injected, the second gas is firstly heated or cooled and then injected from the intake tube into the first interlayer between the external pipeline and the inner pipeline. A first pressure of the first gas is less than a second pressure of the second gas.

Further, the multi-layer heat insulated pipeline according to the second preferred embodiment of the invention also includes a thermal insulation layer and a heating device. The flexible metal hose and the external pipeline are disposed within the thermal insulation layer. The intake tube extending outside the thermal insulation layer. A second interlayer, between the thermal insulation layer and the external pipeline, is vacuumized. The heating device is attached to an outer periphery of the external pipeline. The heating device is configured to heat the external pipeline.

Further, the multi-layer heat insulated pipeline according to the second preferred embodiment of the invention also includes a plurality of thermal insulation supporting members. These thermal insulation supporting members are intermittently disposed on the outer periphery of the external pipeline to space apart an inner periphery of the thermal insulation layer from the heating device.

In one embodiment, an average pitch of the plurality of slits ranges from 0.1 micrometers to 5000 micrometers.

In one embodiment, a distribution density of the plurality of slits ranges from 0.001 to 100 slits per centimeter pipeline length.

Distinguishable from the prior arts, the multi-layer heat insulated pipeline according to the invention utilizes a temperature-and flow-controlled second gas (a non-reactive gas) injected into the interlayer between the external pipeline and the inner pipeline or the flexible metal hose, which then permeates into the inner pipeline or the flexible metal hose. In accordance with vacuum flow dynamics, the permeated second gas forms a gas curtain on the inner wall of the inner pipeline or the flexible metal hose, preventing the first gas from depositing particles or process by-products that could cause clogging. Furthermore, the vacuumized interlayer between the thermal insulation layer and the external pipeline minimizes heat transfer by conduction and convection. This design significantly reduces heat loss during temperature control, enhances energy efficiency, and ensures stable fluid temperature, achieving superior heating and insulation effects. The invention offers high heating efficiency, reduced assembly time due to its modular and flexible design, and eliminates the need for extra fittings and heating devices for bends.

The advantage and spirit of the invention may be understood by the following recitations together with the appended drawings.

### BRIEF DESCRIPTION OF THE APPENDED DRAWINGS

FIG. 1 is a partial cross-sectional view of a multi-layer heat insulated pipeline according to a first preferred embodiment of the invention.

FIG. 2 is a partial cross-sectional view of a multi-layer heat insulated pipeline according to a second preferred embodiment of the invention.

FIG. 3 is a diagram showing the power consumption over time for an example of the invention and a comparative example, both maintained at 180° C. with a 100 SLM flow of room-temperature nitrogen.

FIG. 4 is an external photograph of the inlet end of the pipeline of the comparative example after 90 days of continuous use.

FIG. 5 is an external photograph of the outlet end of the pipeline of the comparative example after 90 days of continuous use.

FIG. 6 is an external photograph of the inlet end of the multi-layer heat insulated pipeline of the example of the invention after 90 days of continuous use.

FIG. 7 is an external photograph of the outlet end of the multi-layer heat insulated pipeline of the example of the invention after 90 days of continuous use.

### DETAILED DESCRIPTION OF THE INVENTION

Some preferred embodiments and practical applications of this present invention would be explained in the following paragraph, describing the characteristics, spirit, and advantages of the invention.

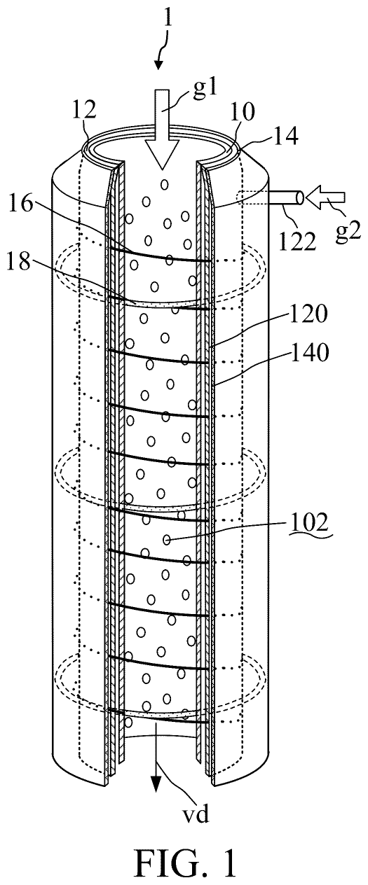

Referring to FIG. 1, FIG. 1 with the partial cross-sectional view schematically illustrates a multi-layer heat insulated pipeline 1 for conveying a first gas g1 according to the first preferred embodiment of the invention. The multi-layer heat insulated pipeline 1 according to the first preferred embodiment of the invention can be used to connect various apparatus and equipment in gas delivery or exhaust systems within semiconductor and optoelectronic manufacturing fields. The first gas g1 may be a process tail gas exhausted from a system, represented by a two-dimensional arrow in FIG. 1.

As shown in FIG. 1, the multi-layer heat insulated pipeline 1 for conveying the first gas g1, according to the first preferred embodiment of the invention, includes an inner pipeline 10 and an external pipeline 12.

The first gas g1 is conveyed within the inner pipeline 10 along a pumping direction vd. The inner pipeline 10 has a plurality of orifices 102 and is disposed within the external pipeline 12. The external pipeline 12 includes an intake tube 122. The inlet of the intake tube 122 can be positioned near the head end of the multi-layer insulated pipeline 1 according to the first preferred embodiment of the invention (i.e., close to the first gas g1 inlet), but the invention is not limited thereto. The outlet of the intake tube 122, in turn, communicates with a first interlayer between the external pipeline 12 and the inner pipeline 10.

A second gas g2 is selectively injected from the intake tube 122 of the external pipeline 12 into the first interlayer between the external pipeline 12 and the inner pipeline 10. The second gas g2 is non-reactive with respect to the first gas g1, such as nitrogen or an inert gas like argon. The injection of the second gas g2 depends on the condition of the first gas g1. For instance, if the first gas g1 has a low particle content or is less reactive, the second gas g2 may not be needed.

When the second gas g2 is injected into the first interlayer between the external pipeline 12 and the inner pipeline 10 from the intake tube 122 of the external pipeline 12, the second gas g2 is firstly heated or cooled and flow-controlled (the flow rate may be zero) before being injected into the first interlayer between the external pipeline 12 and the inner pipeline 10 from the intake tube 122 of the external pipeline 12. The temperature and flow rate (which may also be zero, meaning no injection) of the second gas g2 can be selectively adjusted and injected based on the state of the first gas g1 (e.g., gas reactivity, viscosity, microparticle content, etc.). Specifically, the inlet pressure p1 of the first gas g1 is less than the second pressure p2 of the second gas g2. As a result, the temperature- and flow-controlled second gas g2 will permeate into the inner pipeline 10 that transports the first gas g1. Due to the vacuum flow characteristics within the inner pipeline 10, the permeated temperature-controlled second gas g2 forms a gas curtain on the inner wall of the inner pipeline 10, preventing particle deposition or process by-product deposition of the first gas g1 during transportation, thereby preventing blockage of the inner pipeline 10. In FIG. 1, the second gas g2 is also represented by a two-dimensional arrow.

In one embodiment, the inner pipeline 10 can be a flexible metal hose. This allows the inner pipeline 10 to be bent.

In one embodiment, the external pipeline 12 can be a corrugated pipeline with a compressible pitch configuration. This allows the external pipeline 12 to be bent.

In one embodiment, an average pore diameter of the plurality of orifices 102 ranges from 1 micrometer to 10 millimeters. By adjusting the average pore diameter of the plurality of orifices 102, the permeation range and flow field of the temperature-and flow-controlled second gas g2 into the inner pipeline 10 can be controlled.

In one embodiment, a distribution density of the plurality of orifices 102 ranges from 0.001 to 1000 orifices per centimeter pipeline length. By adjusting the distribution density range of the plurality of orifices 102, the permeation range and flow field of the temperature-and flow-controlled second gas g2 into the inner pipeline 10 can be controlled.

In one embodiment, the distance between any two adjacent orifices 102 of the plurality of orifices 102 ranges from 5 micrometers to 5 meters.

Further, also as shown in FIG. 1, the multi-layer heat insulated pipeline 1 according to the first preferred embodiment of the invention also includes a thermal insulation layer 14 and a heating device 16. The inner pipeline 10 and the external pipeline 12 are disposed within the thermal insulation layer 14, and the intake tube 122 extends outside the thermal insulation layer 14. The thermal insulation layer 14 is an airtight, flexible bellows that isolates the heating device 16 from the external environment. A second interlayer formed between the thermal insulation layer 14 and the external pipeline 12 is vacuumized after assembly to create a thermal barrier (vacuum level <1 atm). The heating device 16 is attached to and in direct contact with an outer periphery 120 of the external pipeline 12 for direct heating. The vacuum in the second interlayer substantially reduces heat dissipation and loss from the heating device 16, making the heating of the multi-layer heat insulated pipeline 1 according to the first preferred embodiment of the invention extremely energy-efficient.

Further, as shown in FIG. 1, the multi-layer heat insulated pipeline 1 according to the first preferred embodiment of the invention also includes a plurality of thermal insulation supporting members 18. The plurality of thermal insulation supporting members 18 are disposed intermittently on the outer periphery 120 of the external pipeline 12 and contact an inner periphery 140 of the thermal insulation layer 14. The outer diameter of the supporting members 18 is greater than that of the heating device 16, thereby spacing apart the thermal insulation layer 14 from the heating device 16 to prevent direct contact. Consequently, the heating device 16 does not transfer heat through contact with the thermal insulation layer 14, and the vacuum in the second interlayer between the thermal insulation layer 14 and the outer pipeline 12 ensures its insulation effectiveness.

In one embodiment, the vacuum value of the vacuumized second interlayer can range from 1×10⁻⁸ torr to 760 torr. This range of vacuum values can provide varying degrees of thermal insulation effectiveness

The thermal conductivities of the various cladding materials used for insulation in the aforementioned prior art indirect heating devices are described below. The thermal conductivity of a cloth made of Nomex heat-resistant fiber is approximately 0.04 to 0.06 W/(m·K). The thermal conductivity of silicone is about 0.2 to 0.3 W/(m·K). The thermal conductivity of aerogel is between 0.01 and 0.02 W/(m·K).

In the multi-layer insulated pipeline 1, according to the first preferred embodiment of the invention, a vacuumized second interlayer is employed to block heat transfer from the multi-layer insulated pipeline 1 to the outside. The relationship between the vacuum level of the second interlayer and the corresponding thermal conductivity, using nitrogen gas as an example, is as follows: when the vacuum level is at atmospheric pressure (˜1 atm), the thermal conductivity of nitrogen is approximately 0.025 W/(m·K); at a low vacuum (˜0.1 atm), it significantly decreases to approximately 0.002 to 0.005 W/(m·K); at a medium vacuum (˜0.01 atm), it is further reduced to about 0.0002 to 0.0005 W/(m·K); at a high vacuum (˜0.001 atm), the thermal conductivity is extremely low, approximately 0.00002 W/(m·K); and at an ultra-high vacuum (˜10⁻⁵ atm or lower), the thermal conductivity of nitrogen approaches zero, potentially on the order of 10⁻⁸ W/(m·K) or less.

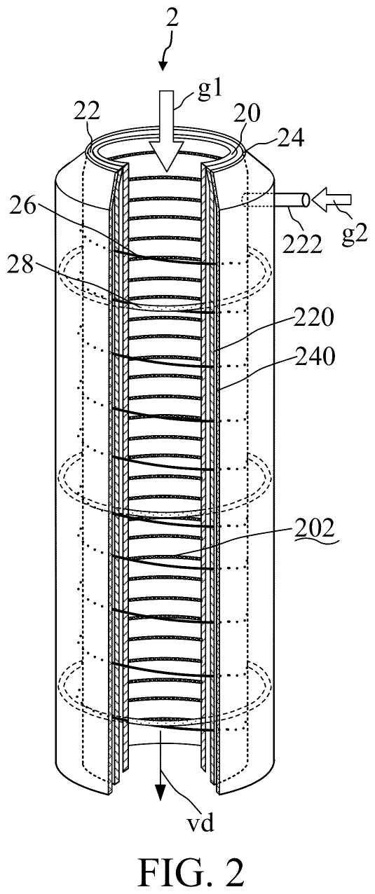

Referring to FIG. 2, FIG. 1 with the partial cross-sectional view schematically illustrates a multi-layer heat insulated pipeline 2 for conveying a first gas g1 according to a second preferred embodiment of the invention. The multi-layer heat insulated pipeline 2 according to the second preferred embodiment of the invention can be used to connect various apparatus and equipment in gas delivery or exhaust systems within semiconductor and optoelectronic manufacturing fields. The first gas g1 may be a process tail gas exhausted from a system, represented by a two-dimensional arrow in FIG. 2.

As shown in FIG. 2, the multi-layer heat insulated pipeline 2 for conveying the first gas g1, according to the second preferred embodiment of the invention, includes a flexible metal hose 20 and an external pipeline 22. The first gas g1 is conveyed within the flexible metal hose 20 along a pumping direction vd. The flexible metal hose 20 has a plurality of slits 202. In other words, the flexible metal hose 20 can be a corrugated pipeline, a pipeline with a metal snap-lock interlocked design, or a flexible metal channel similar to a coupling, manufactured by laser cutting.

The flexible metal hose 20 is disposed within the external pipeline 22. The external pipeline 22 includes an intake tube 222. The external pipeline 22 includes an intake tube 222. The inlet of the intake tube 222 can be positioned near the head end of the multi-layer insulated pipeline 2 according to the second preferred embodiment of the invention (i.e., close to the first gas g1 inlet), but the invention is not limited thereto. The outlet of the intake tube 222, in turn, communicates with a first interlayer between the external pipeline 22 and the flexible metal hose 20.

A second gas g2 is selectively injected from the intake tube 222 of the external pipeline 22 into the first interlayer between the external pipeline 22 and the flexible metal hose 20. The second gas g2 is non-reactive with respect to the first gas g1, such as nitrogen or an inert gas like argon. The injection of the second gas g2 depends on the condition of the first gas g1. For instance, if the first gas g1 has a low particle content or is less reactive, the second gas g2 may not be needed.

When the second gas g2 is injected into the first interlayer between the external pipeline 22 and the flexible metal hose 20 from the intake tube 222 of the external pipeline 22, the second gas g2 is firstly heated or cooled and flow-controlled (the flow rate may be zero) before being injected into the first interlayer between the external pipeline 22 and the flexible metal hose 20 from the intake tube 222 of the external pipeline 22. The temperature and flow rate (which may also be zero, meaning no injection) of the second gas g2 can be selectively adjusted and injected based on the state of the first gas g1 (e.g., gas reactivity, viscosity, microparticle content, etc.). Specifically, the inlet pressure p1 of the first gas g1 is less than the second pressure p2 of the second gas g2. As a result, the temperature- and flow-controlled second gas g2 will permeate into the flexible metal hose 20 that transports the first gas g1. Due to the vacuum flow characteristics within the flexible metal hose 20, the permeated temperature-controlled second gas g2 forms a gas curtain on the inner wall of the flexible metal hose 20, preventing particle deposition or process by-product deposition of the first gas g1 during transportation, thereby preventing blockage of the flexible metal hose 20. In FIG. 2, the second gas g2 is also represented by a two-dimensional arrow.

Furthermore, also as shown in FIG. 2, the multi-layer insulated pipeline 2 according to the second preferred embodiment of the invention also includes a thermal insulation layer 24 and a heating device 26. The flexible metal hose 20 and the external pipeline 22 are installed inside the thermal insulation layer 24. The inlet of the intake tube 222 extends outside the thermal insulation layer 24. The thermal insulation layer 24 is primarily a gas-tight and stretchable metal thin film, which serves to prevent the heating device 26 from being directly exposed to the external environment, and which forms a second interlayer with the external pipeline 22. After the multi-layer insulated pipeline 2 is assembled, the second interlayer is vacuum-pumped to achieve a vacuum environment and create a thermal barrier. The heating device 26 is attached to and directly contacts the outer periphery 220 of the external pipeline 22. The heating device 26 is used to directly heat the external pipeline 22. Because the second interlayer between the thermal insulation layer 24 and the external pipeline 22 is in a vacuum state, heat dissipation and loss from the heating device 26 to the outside are significantly reduced. Therefore, heating the multi-layer insulated pipeline 2 according to the second preferred embodiment of the invention is extremely energy-efficient.

Furthermore, also as shown in FIG. 2, the multi-layer insulated pipeline 2 according to the second preferred embodiment of the invention also includes a plurality of thermal insulation supporting members 28. The plurality of thermal insulation supporting members 28 are disposed intermittently on the outer periphery 220 of the external pipeline 22 and contact the inner periphery 240 of the thermal insulation layer 24. The outer diameter of the thermal insulation supporting members 28 is greater than the outer diameter of the heating device 26, serving to space the inner periphery 240 of the thermal insulation layer 24 from the heating device 26 and prevent the thermal insulation layer 24 from contacting the heating device 26. Consequently, the heating device 26 does not transfer heat through contact with the thermal insulation layer 24, and the vacuum in the second annular space between the thermal insulation layer 24 and the external pipeline 22 ensures its insulation effectiveness.

In one embodiment, the external pipeline 22 can be a corrugated pipe with a compressible pitch configuration. This allows the external pipeline 22 to be bent.

In one embodiment, an average pitch of the plurality of slits 202 can range from 0.1 micrometers to 5000 micrometers. By adjusting the average pitch of the plurality of slits 202, the permeation range and flow field of the temperature-and flow-controlled second gas g2 into the flexible metal hose 20 can be controlled.

In one embodiment, a distribution density of the plurality of slits ranges from 0.001 to 100 slits per centimeter pipeline length. By adjusting the distribution density of the plurality of slits 202, the permeation range and flow field of the temperature- and flow-controlled second gas g2 into the flexible metal hose 20 can be controlled.

One example of the multi-layer insulated pipeline according to the present invention utilizes an interlocking flexible metal hose with slits, where its inner diameter is comparable to the diameter of an NW50 pipeline (50 mm), and the length of the interlocking, slit-bearing, flexible metal hose is equal to 1.5 m.

This example places the interlocking flexible metal hose inside a corrugated external pipeline, with the heating device wrapped around the outer periphery of the corrugated external pipeline. This example also installs the interlocking flexible metal hose and the corrugated external pipeline within a thermal insulation layer. The heating device is prevented from directly contacting the inner periphery of the thermal insulation layer by using thermal insulation supporting members between the thermal insulation layer and the corrugated external pipeline. Furthermore, the interlayer between the thermal insulation layer and the corrugated external pipeline is vacuum-pumped to block heat transfer.

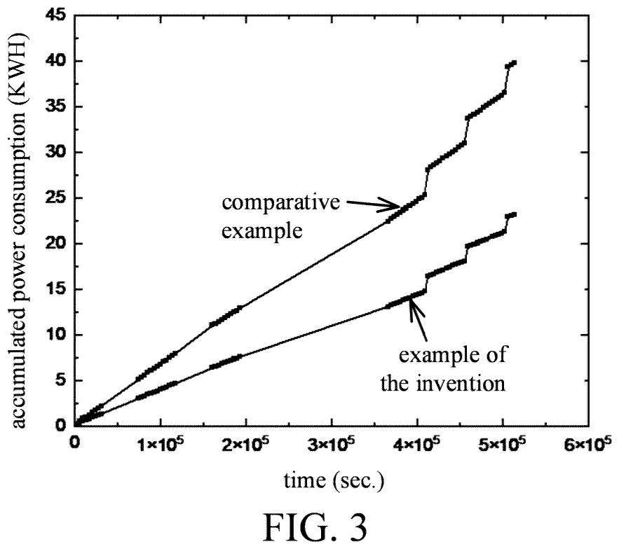

Referring to FIG. 3, FIG. 3 shows the power consumption measurement results over time for an example of the multi-layer insulated pipeline performing the second preferred embodiment of the invention. This measurement is taken while the pipeline is stably maintained at 180° C. with an additional flow of 100 SLM of ambient temperature nitrogen gas. For comparison, the comparative example utilized an NW50 pipeline, an indirect heating device secured between two 5 mm thick silicone sheets, and this indirect heating device is wrapped around the outer periphery of the NW50 pipeline. The power consumption measurement results over time for the comparative pipeline, heated to and maintained at 180° C., are also shown in FIG. 3. The results in FIG. 3 indicate that, when compared to the comparative example, the power consumption of the multi-layer insulated pipeline example of the invention can be reduced by over 30% of the comparative example's power consumption.

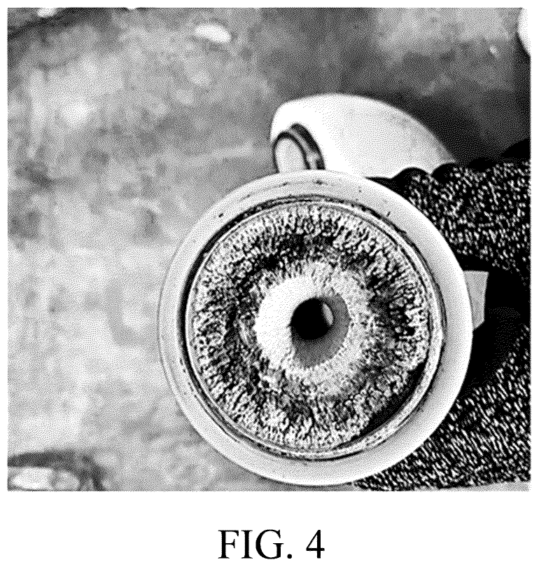

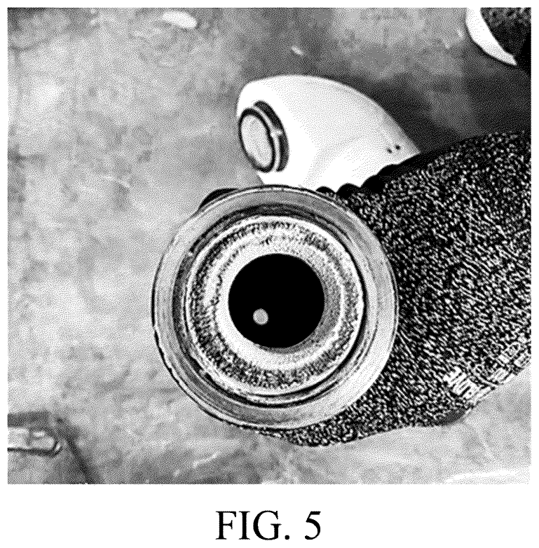

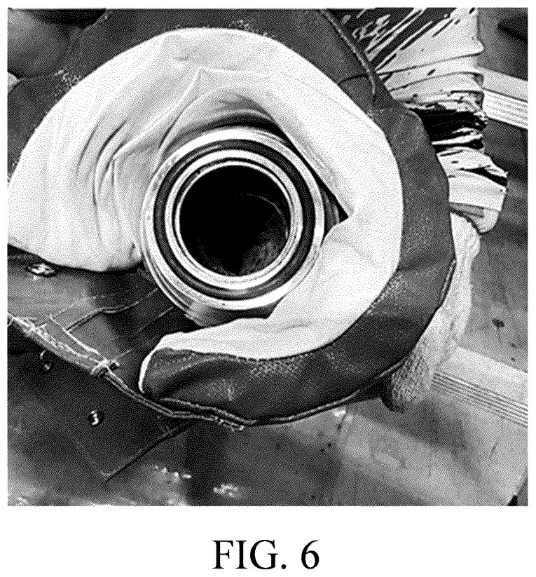

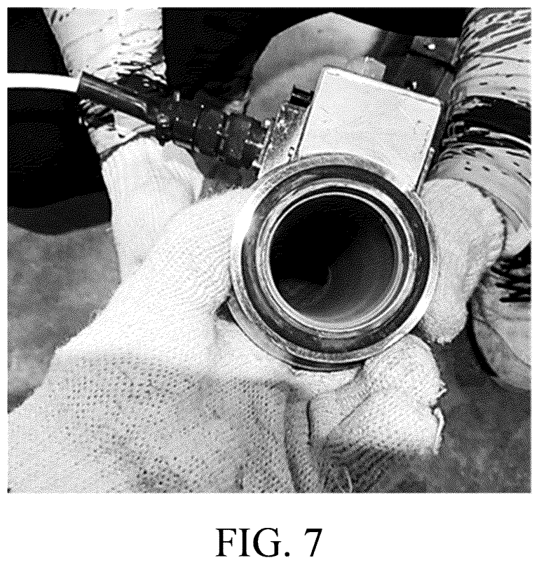

Referring to FIG. 4, FIG, 5, FIG. 6, and FIG. 7, FIG. 4 is an external photograph of the inlet end of the pipeline of the comparative example after 90 continuous days of use on the machine. FIG. 5 is an external photograph of the outlet end of the pipeline of the comparative example after 90 continuous days of use on the machine. FIG. 6 is an external photograph of the inlet end of the multi-layer insulated pipeline of the example of the present invention after 90 continuous days of use on the machine. FIG. 7 is an external photograph of the outlet end of the multi-layer insulated pipeline of the example of the invention after 90 continuous days of use on the machine. FIGS. 4 and 5 confirm that the inner walls of the pipeline of the comparative example are severely blocked with clear particle deposition at both the inlet and outlet ends after 90 continuous days of use on the machine. In contrast, FIGS. 6 and 7 confirm that there is no obvious particle deposition on the inner walls of the multi-layer insulated pipeline of the example of the present invention at either the inlet or outlet end after 90 continuous days of use on the machine

The detailed description above makes it clear that the multi-layer insulated pipeline according to the invention utilizes a temperature-and flow-controlled second gas (a non-reactive gas), injected into the external pipeline, which then slightly permeates into the inner pipeline that transports the first gas. In accordance with vacuum flow dynamics, the permeated temperature-and flow-controlled second gas forms a gas curtain on the inner wall of the inner pipeline, preventing the first gas from depositing particles or accumulating deposits and process by-products due to incomplete reactions, thereby avoiding clogging of the inner pipeline. Furthermore, through the method of heating device placement and the vacuum insulation of the interlayer between the thermal insulation layer and the external pipeline, the multi-layer insulated pipeline achieves extremely high heating efficiency and exceptional energy efficiency for temperature maintenance. The modular and flexible configuration of the multi-layer insulated pipeline according to the invention results in shorter setup and assembly times, and since it can even be bent, it eliminates the need for extra fittings and additional heating devices.

With the examples and explanations described above, the characteristics and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A multi-layer heat insulated pipeline for conveying a first gas, comprising:
an inner pipeline within which the first gas is conveyed along a pumping direction, the inner pipeline having a plurality of orifices; and
an external pipeline, wherein the inner pipeline is disposed within the external pipeline, the external pipeline includes an intake tube, wherein a second gas is selectively injected from the intake tube into a first interlayer between the external pipeline and the inner pipeline, the
second gas being non-reactive with respect to the first gas, wherein the second gas is firstly heated or cooled and then injected from the intake tube into the first interlayer between the external pipeline and the inner pipeline, and wherein a first pressure of the first gas is less than a second pressure of the second gas.

2. The multi-layer heat insulated pipeline of claim 1, further comprising:
a thermal insulation layer, wherein the inner pipeline and the external pipeline are disposed within the thermal insulation layer, and the intake tube extends outside the thermal insulation layer, wherein a second interlayer between the thermal insulation layer and the external pipeline is vacuumized; and
a heating device, attached to an outer periphery of the external pipeline, the heating device being configured to heat the external pipeline.

3. The multi-layer heat insulated pipeline of claim 2, further comprising:
a plurality of thermal insulation supporting members, disposed intermittently on the outer periphery of the external pipeline to space apart an inner periphery of the thermal insulation layer from the heating device.

4. The multi-layer heat insulated pipeline of claim 1, wherein an average pore diameter of the plurality of orifices ranges from 1 micrometer to 10 millimeters.

5. The multi-layer heat insulated pipeline of claim 1, wherein a distribution density of the plurality of orifices ranges from 0.001 to 1000 orifices per centimeter pipeline length.

6. A multi-layer heat insulated pipeline for conveying a first gas, comprising:
a flexible metal hose within which the first gas is conveyed along a pumping direction, the flexible metal hose having a plurality of slits; and
an external pipeline, wherein the flexible metal hose is disposed within the external pipeline, the external pipeline includes an intake tube, wherein a second gas is selectively injected from the intake tube into a first interlayer between the external pipeline and the flexible metal hose, the second gas being non-reactive with respect to the first gas, wherein the second gas is firstly heated or cooled and then injected from the intake tube into the first interlayer between the external pipeline and the flexible metal hose, and wherein a first pressure of the first gas is less than a second pressure of the second gas.

7. The multi-layer heat insulated pipeline of claim 6, further comprising:
a thermal insulation layer, wherein the flexible metal hose and the external pipeline are disposed within the thermal insulation layer, and the intake tube extends outside the thermal insulation layer, wherein a second interlayer between the thermal insulation layer and the external pipeline is vacuumized; and
a heating device, attached to an outer periphery of the external pipeline, the heating device being configured to heat the external pipeline.

8. The multi-layer heat insulated pipeline of claim 7, further comprising:
a plurality of thermal insulation supporting members, disposed intermittently on the outer periphery of the external pipeline to space apart an inner periphery of the thermal insulation layer from the heating device.

9. The multi-layer heat insulated pipeline of claim 6, wherein an average pitch of the plurality of slits ranges from 0.1 micrometers to 5000 micrometers.

10. The multi-layer heat insulated pipeline of claim 6, wherein a distribution density of the plurality of slits ranges from 0.001 to 100 slits per centimeter pipeline length.
